(19) United States
(12) Patent Application Publication
(10) Pub. No.: US 2003/0148564 A1
(43) Pub. Date: Aug. 7, 2003

(54) Method for suppressing short channel effect of a semiconductor device

(76) Inventor: Kent Kuohua Chang, Taipei (TW)

Correspondence Address: J.C. Patents, Inc., Suite 250, 4 Venture, Irvine, CA, 92618, US

(21) Appl. No.: 10/099,800

(22) Filed: Mar. 13, 2002

(30) Foreign Application Priority Data
Feb. 6, 2002 (TW) 91102058

(51) Int. Cl. H01L 21/8238

(52) U.S. Cl. 438/200

(57) ABSTRACT

A method to suppress the short channel effect of a semiconductor device is described. The method provides a substrate having a gate structure formed thereon. A source/drain extension region and a source/drain region formed in the substrate beside the gate structure. A pocket ion implantation process is conducted to form a pocket doped region underneath the source/drain extension region. A rapid thermal process is conducted subsequent to the formation of the source/drain extension region, the source/drain region and the pocket doped region.

### CROSS-REFERENCE TO RELATED APPLICATION

This application claims the priority benefit of Taiwan application serial no. 91102058, filed Feb. 6, 2002.

### BACKGROUND OF THE INVENTION

1. Field of the Invention

The present invention relates to a method for suppressing the short channel effect of a semiconductor device. More particularly, the present invention relates to a method for suppressing the short channel effect by using pocket implantation.

2. Background of the Invention

Flash memory is an electrically erasable programmable read-only memory (EEPROM) that is widely used in computer and microprocessor systems for permanently storing information that are repeatedly read, written or erased. Moreover, flash memory can retain information even when power is interrupted. Flash memory is a type of nonvolatile memory (NVM), which is small in size, faster in reading/programming speed and consumes less power and energy. Since the erasure of information for a flash memory is accomplished “block-by-block”, the operational speed is also faster.

FIGS. 1A to 1E are schematic diagrams in a cross-sectional view illustrating the fabrication of a semiconductor device according to the prior art.

As shown in FIG. 1A, a substrate 100 is provided. A gate structure 106 is formed on the substrate 100. The gate structure 106 includes a gate oxide layer 102 and a gate conductive layer 104. Using the gate structure 106 as an implantation mask, an ion implantation 107 is conducted to form a source/drain extension region 108 in the substrate 100 beside the gate structure 106.

Referring to FIG. 1B, a spacer 110 is formed on the sidewall of the gate structure 106. Using the spacer 110 and the gate structure 106 as an implantation mask, an ion implantation 111 is conducted to form a source/drain region 112 in the substrate 100 beside the spacer 110.

Continuing to FIG. 1C, a first thermal process is conducted, wherein the first thermal process is to anneal the source/drain extension region 108 and the source/drain regions 112 in order to repair the lattice defects created during the ion implantation process 107 and 111.

Referring to FIG. 1D, a pocket implantation 114 also known as a halo implantation is conducted to form a pocket doped region 116 under the source/drain extension region 108. The type of dopants implanted in the pocket doped region 116 is different from the type of dopants implanted in the source/drain extension region 108 and in the source/drain region 112. The shallow junction formation is to suppress the short channel effect of the semiconductor device. For a typical N channel metal oxide semiconductor device (NMOS), boron ions are conventionally used to form the pocket doped region 116.

Continuing to FIG. 1E, a second thermal process is conducted, wherein the second thermal process is to anneal the pocket doped region 116 in order to repair the lattice defects created during the pocket implantation 114.

Although conventionally, methods have been developed to suppress the short channel effect in a semiconductor device. An example of such includes, as discussed above, forming a pocket doped region 116 under the source/drain extension region to suppress the short channel effect. The conventional method, however, fails to consider the fast diffusion of dopants in the pocket doped region to effectively suppress the short channel effect.

Moreover, in the aforementioned method to suppress the short channel effect in a semiconductor device, a first thermal process is conducted to form the source/drain extension region and the source/drain region. Since the first thermal process repairs the lattice defects formed during the implantation processes 107, 111, the second thermal process, conducted subsequent to the formation of the pocket implantation, will cause the dopants in the pocket doped region to diffuse.

### SUMMARY OF THE INVENTION

The present invention provides a method to suppress the short channel effect of a semiconductor device, wherein the diffusion of dopants in the pocket doped region is mitigated in order to suppress the short channel effect in a semiconductor device.

The present invention also provides a method to suppress the short channel effect of a semiconductor device, wherein a diffusion of the dopants in the pocket doped region due to the subsequent thermal process is prevented.

The present invention provides a method to suppress the short channel effect of a semiconductor device. A substrate is provided and a gate structure is formed on the substrate. A first ion implantation process is conducted to form a source/drain extension region using the gate structure as an implantation mask. The dopants used for the first ion implantation process include antimony or arsenic. After this, a spacer is formed on the sidewall of the gate structure, and a second ion implantation process is conducted to form a source/drain region beside the spacer in the substrate. A pocket implantation is conducted to form a pocked doped region under the source/drain extension region, wherein the dopants used for the pocket implantation includes indium. Subsequent to the formation of the pocket doped region, a thermal process is conducted to anneal the source/drain extension region, the source/drain region and the pocket doped region.

The present invention provides a method to suppress the short channel effect of a semiconductor device, wherein a thermal process is not performed after the formation of the source/drain extension region and the source/drain region. The lattice defects formed during the implantation process are not repaired. The dopants in the pocket doped region are then trapped in the lattice defects to reduce the diffusion of the dopants in the pocket doped region during the subsequent thermal process.

The present invention provides a method to suppress the short channel effect, wherein indium ions are used to replace the conventional boron ions in forming the pocket doped region. Since indium ions are heavier than boron ions, indium ions diffuse at a slower rate. The diffusion of dopants from the pocket doped region thus reduces.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A to 1E are schematic diagrams in a cross-sectional view illustrating the fabrication of a semiconductor device according to the prior art; and

FIGS. 2A to 2C are schematic diagrams in a cross-sectional view illustrating the fabrication of a semiconductor device according one embodiment of the present invention.

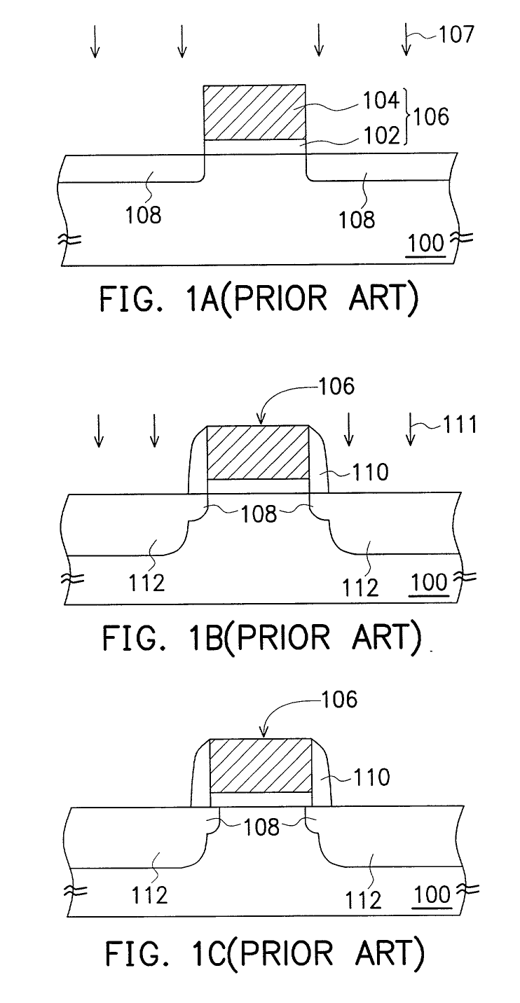

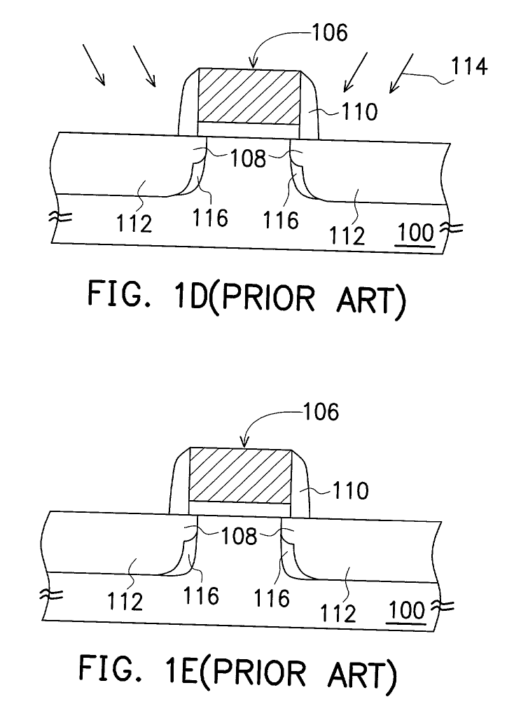

### DESCRIPTION OF THE PREFERRED EMBODIMENTS

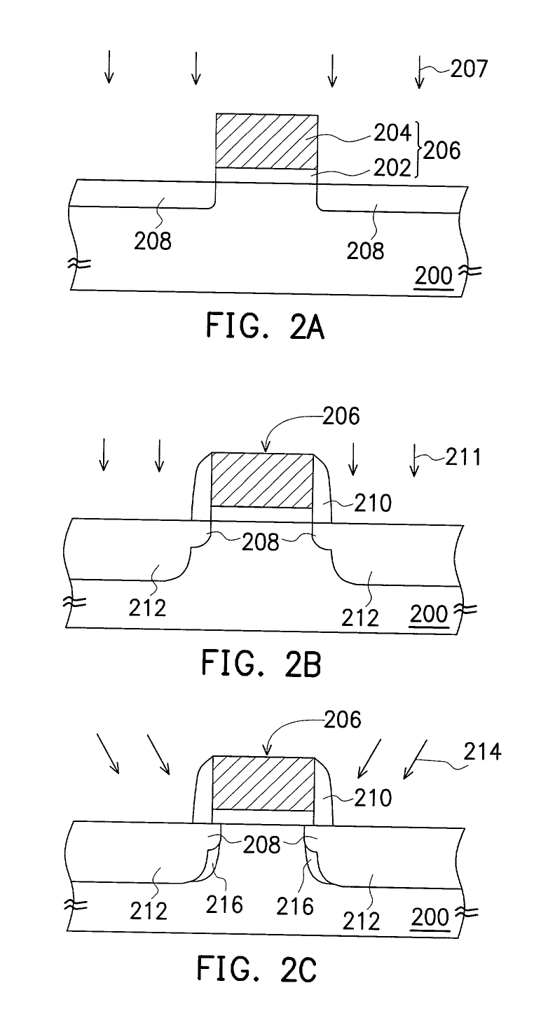

FIGS. 2A to 2C are schematic diagrams in cross-sectional view illustrating the fabrication of a semiconductor device according one embodiment of the present invention.

As shown in FIG. 2A, a substrate 200 is provided, wherein the substrate 200 is, for example, a p-type silicon substrate. A gate structure 206 is formed on the substrate 200. The gate structure 206 includes a gate oxide layer 202 and a gate conductive layer 204, wherein the gate conductive layer 204 is, for example, polysilicon.

Thereafter, using the gate structure 206 as an implantation mask, an ion implantation process 207 is conducted to form a source/drain extension region 208 in the substrate 200 beside the gate structure 206, wherein the source/drain extension region 208 is implanted with N-type dopants. The N-type dopants include antimony ions or arsenic ions. The implantation energy for the ion implantation process 207 is about 10 keV and the dosage of the ion implantation process 207 is about 3×10¹⁴/cm².

As shown in FIG. 2B, a spacer 210 is formed on the sidewall of the gate structure 206. The spacer 210 is formed by forming a conformal dielectric layer on the substrate 200, followed by back-etching the conformal dielectric layer.

After this, using the gate structure 206 and the spacer 210 as an implantation mask, an ion implantation process 211 is conducted to form a source/drain region 212 in the substrate 200 beside the spacer 210. The dopants implanted in the source/drain region are same as those implanted in the source/drain extension region 208. As discussed in the above, the dopants implanted for the source/drain region 212 include antimony ions or arsenic ions.

Referring to FIG. 2C, subsequent to the formation of the source/drain extension region 208 and the source/drain region 212, a pocket doped implantation 214 is conducted to form a pocked doped region 216 under the source/drain extension region 208. The dopants implanted for the pocket doped region 216 includes a p-type dopant. According to the preferred embodiment of the present invention, the dopants used for the pocket doped region 216 includes indium ions. The implantation energy for the pocket doped implantation process 214 is about 10 keV. The dosage of the pocket doped implantation process 214 is about 3×10¹⁴/cm². The pocket doped implantation process 214 tilt angle is about 30 degrees.

After the formation of the pocket doped region 216, a thermal process is conducted to anneal the source/drain extension region 208, the source/drain region 212 and the pocket doped region 216 concurrently to repair the lattice defects formed during the above implantation processes 207, 211, 214. The thermal process is, for example, a rapid thermal process, conducted at a temperature of about 900 degrees Celsius for about 10 seconds.

Since in the present invention, a thermal process is not performed after the formation of the source/drain extension region 208 and the source/drain region 212, the lattice defects formed during the implantation processes 207, 211 in forming the source/drain extension region 208 and the source/drain region 212 are not repaired. During the subsequent formation of the pocket doped region 216, the implanted indium ions are trapped in the above lattice defects. The diffusion of the indium ions during the subsequent thermal process is effectively suppressed.

Moreover, since the p-type dopants implanted for the pocket doped region 216 is indium ions and indium ions are heavier than the conventional boron ions. The indium ions thus diffuse at a much slower rate than the boron ions. The indium ions thereby replace the role of the boron ions as the dopants for the pocket doped region to mitigate the diffusion problem in the doped pocket region 216.

According to the method in suppressing the short channel of the present invention, a thermal process is not conducted after the formation of the source/drain extension region and the source/drain region. Lattice defects formed during the ion implantation processes are not repaired. The dopants of the subsequently formed pocket doped region are trapped in the lattice defects to reduce the diffusion of dopants in the pocket doped region during the subsequently performed thermal process.

Additionally, according to the method of the present invention in suppressing the short channel effect, indium ions are used to replace boron ions as the dopants being implanted for the pocket doped region. Since indium ions are heavier than boron ions, the diffusion of dopants in the pocket doped region is retarded.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method to suppress a short channel effect of a semiconductor device, comprising:
forming a gate structure on a substrate;
forming a source/drain extension region and a source/drain region in the substrate beside the gate structure;
performing a pocket ion implantation process to form a pocket doped region under the source/drain extension region; and
performing a rapid thermal process to anneal the source/drain extension region, the source/drain region and the pocket doped region concurrently.

2. The method of claim 1, wherein the source/drain extension region and the source/drain region are implanted with an N-type dopant.

3. The method of claim 2, wherein the N-type dopant is selected from the group consisting of antimony ions and arsenic ions.

4. The method of claim 2, wherein an implantation energy for forming the source/drain extension region is about 10 KeV.

5. The method of claim 2, wherein a dosage that is implanted for the source/drain extension region is about 3×10¹⁴/cm².

6. The method of claim 1, wherein the pocket doped region is doped with a p-type doapnt.

7. The method of claim 6, wherein the p-type dopant includes indium ions.

8. The method of claim 7, wherein an implantation energy for the pocket doped implantation process is about 60 keV.

9. The method of claim 7, wherein a dosage of the pocket doped implantation process is about 1×10¹³/cm².

10. The method of claim 7, wherein the pocket doped implantation tilt angle is about 30 degrees.

11. The method of claim 1, wherein the rapid thermal process is conducted under a temperature of about 900 degrees Celsius for about 10 seconds.

12. A method to suppress a short channel effect of a semiconductor device, comprising:
forming a gate structure on a substrate;
performing a first ion implantation process to form a source/drain extension region in the substrate using the gate structure as an implantation mask;
forming a spacer on a sidewall of the gate structure;
performing a second ion implantation process to form a source/drain region using the spacer as an implantation mask;
performing a pocket doped implantation process to form a pocket doped region under the source/drain extension region after the formation of the source/drain extension region and the source/drain region; and
performing a rapid thermal process after the formation of the pocket doped region to anneal the source/drain extension region, the source/drain region and the pocket doped region.

13. The method of claim 12, wherein a dopant implanted for the source/drain extension region and the source/drain region is selected from the group consisting of antimony ions and arsenic ions.

14. The method of claim 12, wherein an implantation energy for the first ion implantation process is about 10 KeV.

15. The method of claim 12, wherein a dosage of the first ion implantation process is about 3×10¹⁴/cm².

16. The method of claim 12, wherein a dopant implanted for the pocket doped region includes indium ions.

17. The method of claim 16, wherein an implantation energy for the pocket doped implantation is about 60 keV.

18. The method of claim 16, wherein a dosage of the pocket doped implantation process is about 1×10¹³/cm².

19. The method of claim 16, wherein the pocket doped implantation is conducted at a tilt angle of about 30 degrees.

20. The method of claim 12, wherein the rapid thermal process is conducted under a temperature of about 900 degrees Celsius for about 10 seconds.
